(19) United States
(12) Patent Application Publication
(10) Pub. No.: US 2021/0132506 A1
(43) Pub. Date: May 6, 2021

(54) Ionic Liquids as Lubricants in Optical Systems

(71) Applicant: KLA Corporation, Milpitas, CA (US)

(72) Inventors: Zefram Marks, Fremont, CA (US); Gildardo Delgado, Livermore, CA (US); Karl Olof Johansson, Milpitas, CA (US); Brady Clark, Milpitas, CA (US)

(21) Appl. No.: 16/829,486

(22) Filed: Mar. 25, 2020

Related U.S. Application Data
(60) Provisional application No. 62/928,961, filed on Oct. 31, 2019.

(51) Int. Cl. G03F 7/20; C10M 105/72

(52) U.S. Cl. CPC G03F 7/7065; G03F 7/70933; C10N 2020/077; C10M 105/72; C10M 2219/044; G03F 7/70825

(57) ABSTRACT

A system includes optics for ultraviolet light or electrons. The optics are situated in a chamber and include a surface to control a path of photons or electrons. The system also includes a lubricated component that is distinct from the surface and is situated in the chamber. The lubricated component is lubricated with a lubricant that includes an ionic liquid having a cation and an anion, wherein at least one of the cation or the anion is organic.

### RELATED APPLICATION

This application claims priority to U.S. Provisional Patent Application No. 62/928,961, filed Oct. 31, 2019, which is hereby incorporated by reference in its entirety for all purposes.

### TECHNICAL FIELD

This disclosure relates to lubricants, and more specifically to using ionic liquids as lubricants in optical systems (e.g., in systems used for reticle or semiconductor-wafer inspection). The phrase “optical systems” as used herein includes both photonic systems and systems using electron optics.

### BACKGROUND

Radiation (e.g., high-energy photons, such as ultraviolet light, or electrons) can induce contamination on critical surfaces (e.g., optical surfaces) in optical systems. Such contamination can arise from organic, inorganic, and metal compounds. The radiation interacts with contaminants as well as surface materials, resulting in surface-defect formation and ionization and fragmentation of contaminants adsorbed to the surface, which in turn induce surface chemistry. These chemical processes result in undesirable growth of thin contamination films on the critical surfaces. Examples of optical systems that suffer from this problem include inspection tools for semiconductor wafers or reticles.

Such radiation in optical systems can cause contamination that might otherwise have a thickness of a few monolayers to build up to hundreds of nanometers on critical surfaces. For example, carbon deposition is known to occur when optical surfaces in a hydrocarbon environment are exposed to extreme ultraviolet (EUV) light. Carbon contamination on EUV optical elements affects both the absorption and phase of the light, thereby altering the figure of these optics and, thus, also the aberrations. Absorption by deposited carbon not only reduces throughput, but also leads to apodisation of the pupil, which in turn affects imaging performance.

Optical systems that suffer from such contamination may have motors, rails, and/or other parts that require lubrication. Lubricants used in such systems are typically hydrocarbon-, fluorocarbon-, or silicone-based. These lubricants outgas contaminants that contribute to the undesirable growth of thin contamination films on the critical surfaces. Outgassing may be reduced by heating the system in a process referred to as baking or bake-out, during which the rate of release of contaminants accelerates due to the increased temperature. Post-bake outgassing levels for hydrocarbon-, fluorocarbon-, and silicone-based lubricants, however, are still higher than is desirable (e.g., for ultra-clean environments such as inspection tools). Furthermore, these lubricants may outgas contaminants including silicon-containing compounds (e.g., siloxanes) that are especially problematic precursors of thin contamination films on the critical surfaces.

### SUMMARY

Accordingly, there is a need for lubricants with low outgassing for use in systems that include optics for high-energy (e.g., ultraviolet) photons or electrons. This need is met by embodiments disclosed herein, including the following system and method.

In some embodiments, a system includes optics for ultraviolet light or electrons. The optics are situated in a chamber and include a surface to control a path of photons or electrons. The system also includes a lubricated component that is distinct from the surface and is situated in the chamber. The lubricated component is lubricated with a lubricant that includes an ionic liquid having a cation and an anion, wherein at least one of the cation or the anion is organic.

In some embodiments, a method includes disposing optics for ultraviolet light or electrons in a chamber. The optics include a surface to control a path of photons or electrons. The method also includes disposing a lubricated component distinct from the surface in the chamber. The lubricated component is lubricated with a lubricant that includes an ionic liquid having a cation and an anion, wherein at least one of the cation or the anion is organic. The method further includes, within the chamber, moving either the lubricated component or a structure in mechanical contact with the lubricated component.

### BRIEF DESCRIPTION OF THE DRAWINGS

For a better understanding of the various described implementations, reference should be made to the Detailed Description below, in conjunction with the following drawings.

FIG. 1 shows a chamber of an optical system in which an ionic liquid is used as a lubricant, in accordance with some embodiments.

FIG. 2 shows translation stages that may be used in the chamber of FIG. 1 and lubricated with an ionic liquid, in accordance with some embodiments.

FIGS. 3A and 3B show perspective and cross-sectional views, respectively, of a linear motor on a linear-motor rail, both of which may be lubricated with an ionic liquid, in accordance with some embodiments.

FIG. 4 is a graph showing data quantifying the outgassing of semi-volatile organic compounds for seven different ionic liquids, as measured using gas-chromatography mass spectrometry.

FIG. 5 is a flowchart showing a method of fabricating and operating an optical system in accordance with some embodiments.

Like reference numerals refer to corresponding parts throughout the drawings and specification.

### DETAILED DESCRIPTION

Reference will now be made in detail to various embodiments, examples of which are illustrated in the accompanying drawings. In the following detailed description, numerous specific details are set forth in order to provide a thorough understanding of the various described embodiments. However, it will be apparent to one of ordinary skill in the art that the various described embodiments may be practiced without these specific details. In other instances, well-known methods, procedures, components, circuits, and networks have not been described in detail so as not to unnecessarily obscure aspects of the embodiments.

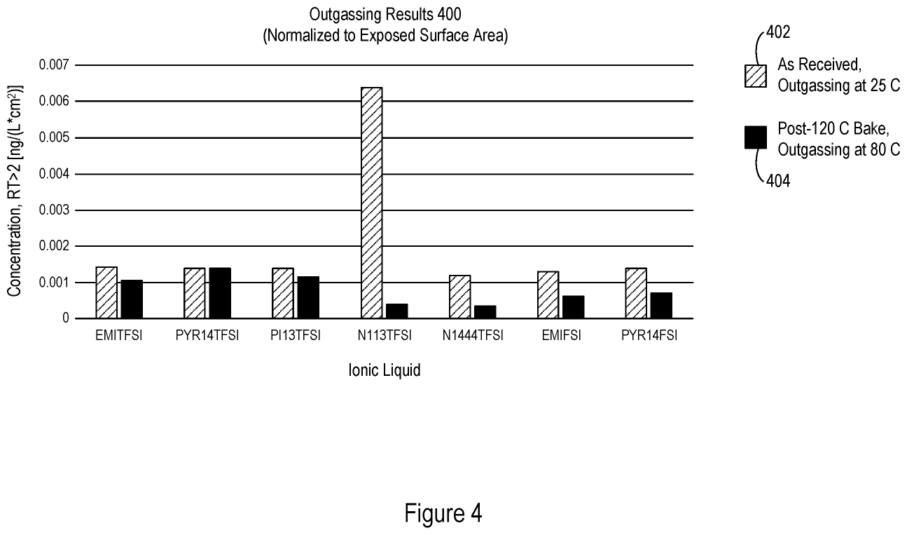

Ionic liquids may be used as lubricants in optical systems to reduce photo-induced or electron-induced formation of thin contamination films on critical surfaces (e.g., optical surfaces or surfaces of electron-beam electrodes). Ionic liquids, as the term is used herein, are salts in which the cation and/or the anion are organic (i.e., at least one of the cation or the anion is organic) and the salt is in the liquid phase at the operational temperature of the optical system. In some embodiments, the cation is organic and the anion is organic. In some other embodiments, the cation is organic and the anion is inorganic. While the cation is typically organic, some ionic liquids have inorganic cations. Due to the ionic character of their intermolecular bonds, ionic liquids have extremely low vapor pressures and, correspondingly, extremely low outgassing rates. Data illustrating low outgassing rates for examples of ionic liquids are presented below with respect to FIG. 4.

In addition to low vapor pressures and outgassing rates, ionic liquids have high temperature stability and are liquid at typical operational temperatures for optical systems in which they may be used (e.g., at room temperature). Ionic liquids have broadly tunable viscosities. For a given application, an ionic liquid may be selected based on its viscosity and tribology. This selection may include consideration of an ionic liquid's ability to wet the material to be lubricated (e.g., as determined by how hydrophobic or hydrophilic the ionic liquid is).

In some embodiments, the ionic liquid used as a lubricant in an optical system is selected from the group consisting of 1-ethyl-3-methylimidazolium bis(trifluoromethanesulfonyl)imide (EMITFSI), 1-butyl-1-methylpyrrolidinium bis(trifluoromethanesulfonyl)imide (PYR14TFSI), 1-methyl-1-propylpiperidinium bis(trifluoromethanesulfonyl)imide (PI13TFSI), N-trimethyl-N-propyl-ammonium bis(trifluoromethanesulfonyl)imide (N1113TFSI), N-methyl-tri-N-butylammonium bis(trifluoromethanesulfonyl)imide (N1444TFSI), 1-ethyl-3-methylimidazolium bis(fluorosulfonyl)imide (EMIFSI), and 1-butyl-1-methylpyrrolidinium bis(fluorosulfonyl)imide (PYR14FSI). The ionic liquids in this group are merely examples of ionic liquids that may be used, others may be used as well. In some embodiments, the ionic liquid used as a lubricant in an optical system has bis(trifluoromethanesulfonyl)imide (TFSI) or bis(fluorosulfonyl)imide (FSI) as the anion.

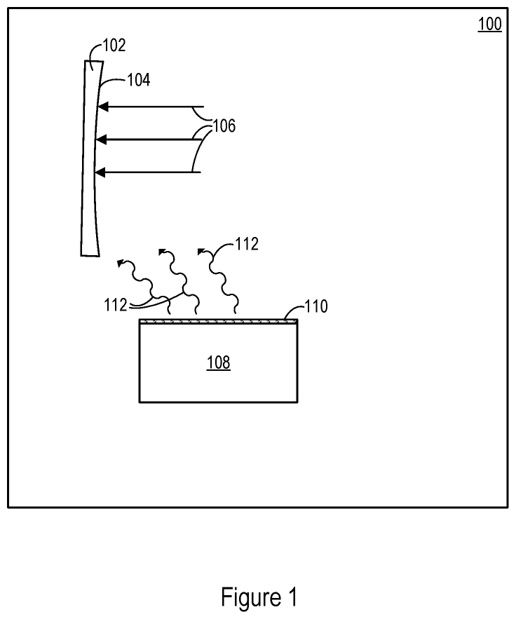

FIG. 1 shows a chamber 100 of an optical system in which an ionic liquid is used as a lubricant, in accordance with some embodiments. Disposed in the chamber 100 are optics including a component 102. (The optics typically include multiple components; only a single component 102 is shown for simplicity.) The component 102 includes a critical surface 104 (e.g., an optical surface or a surface of an electron-beam electrode) that is exposed to radiation 106 (e.g., on which the radiation 106 is incident). Examples of the component 102 include, without limitation, a lens, mirror, polarizer (e.g., analyzer), apodizer, etc. In some embodiments, the radiation 106 includes (e.g., is) ultraviolet light. Examples of ultraviolet light to which the critical surface 104 is exposed may include single ultraviolet wavelengths (e.g., 400 nm or below, or 350 nm or below), broadband deep ultraviolet (DUV) in the wavelength range of 200-400 nm, narrow or broadband vacuum ultraviolet (VUV) in the wavelength range of 120-200 nm, and/or extreme ultraviolet (EUV) (e.g., 13.5 nm). In other embodiments, the radiation 106 is electrons, the optics are electron optics (e.g., the component 102 is an electron-beam electrode), and the optical system is an electron-beam system.

The chamber also includes a lubricated component 108 distinct from the critical surface 104 (e.g., distinct from the optics). The lubricated component 108 is lubricated with a lubricant 110, which includes an ionic liquid. In some embodiments, the lubricant 110 is a neat ionic liquid (i.e., without additives) with a specified purity (e.g., 99.5%). The lubricated component 108 may be a moving part (e.g., a motor or motorized translation stage) or a structure in mechanical contact with a moving part (e.g., a rail). The lubricant 110 outgasses a low level of contaminants 112.

In some embodiments, the chamber 100 is a vacuum chamber. For example, the chamber 100 may be an ultra-high vacuum (UHV) chamber (e.g., of a semiconductor-wafer or reticle inspection system used to identify defects on semiconductor wafers or reticles). (The term UHV is a conventional, well-known technical term referring to vacuums with pressures less than approximately 10⁻⁷ pascal.) In other embodiments, the chamber 100 operates under purge, with purified air flowing through it (e.g., at atmospheric pressure). This air may include oxygen (e.g., for applications with ultraviolet light with wavelengths of 193 nm or greater) or may be oxygen-free (e.g., N2 purge) (e.g., for applications with ultraviolet light with wavelengths less than 193 nm).

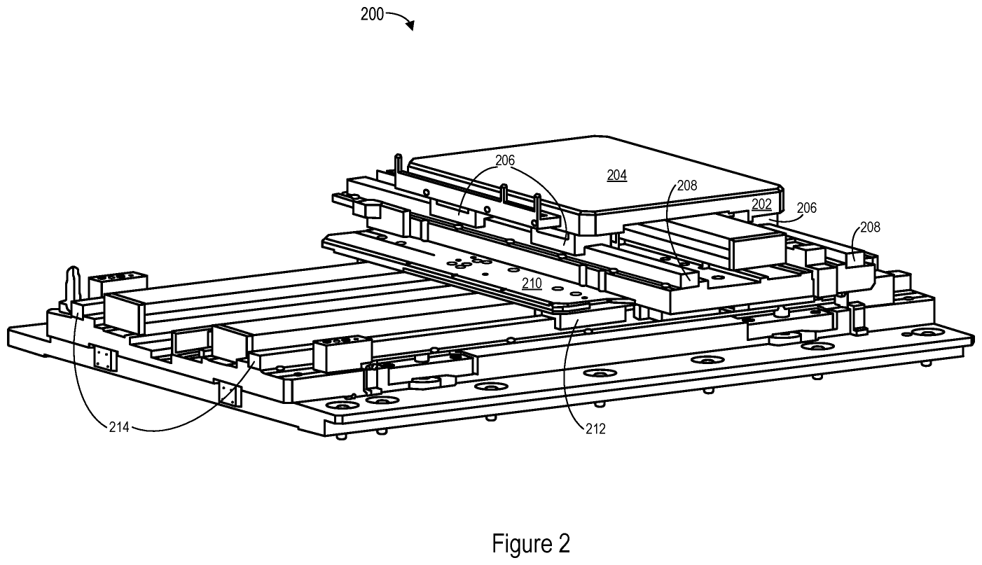

FIG. 2 shows translation stages 200 that may be used in the chamber 100 (FIG. 1) and lubricated with an ionic liquid, in accordance with some embodiments. The translation stages include a first translation stage 202, which has linear motors 206 that move on rails 208. The linear motors 206 and/or rails 208 are examples of lubricated components 108 (FIG. 1) and are thus lubricated with a lubricant 110 (FIG. 1) that includes an ionic liquid (e.g., is a neat ionic liquid). The first translation stage 202 includes a platform 204. In some embodiments, the platform supports a chuck (not shown) (e.g., on which semiconductor wafers or reticles are mounted for inspection). The first translation stage 202 moves in a first direction (e.g., the x-direction) and is disposed on a second translation stage 210 that moves in a second direction (e.g., the y-direction). The second translation stage 210 has linear motors 212 that move on rails 214 in the second direction. The linear motors 212 and/or rails 214 are also examples of lubricated components 108 (FIG. 1) and are thus lubricated with a lubricant 110 (FIG. 1) that includes an ionic liquid (e.g., is a neat ionic liquid). The linear motors 212 and/or rails 214 may be lubricated with the same lubricant 110 as the linear motors 206 and/or rails 208 or with a different lubricant 110.

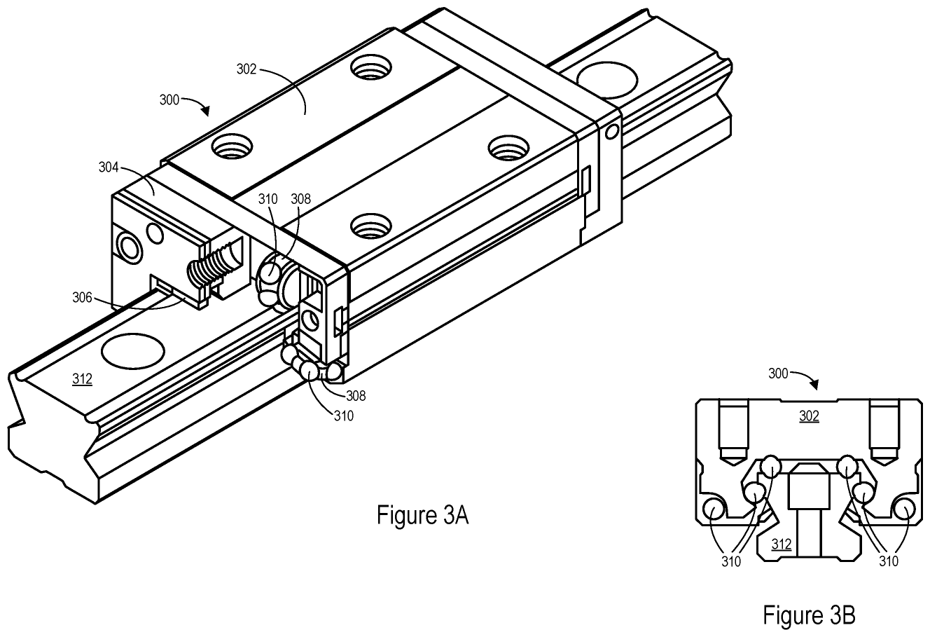

FIGS. 3A and 3B show perspective and cross-sectional views, respectively, of a linear motor 300 on a linear-motor rail 312, in accordance with some embodiments. The linear motor 300 is an example of a linear motor 206 or 212 (FIG. 2). The linear-motor rail 312 is an example of a rail 208 or 214 (FIG. 2). The linear motor 300 and/or linear-motor rail 312 thus are examples of lubricated components 108 used in the chamber 100 (FIG. 1). The linear motor 300 includes a linear-motor block 302, endplate 304, and end seal 306. The linear motor 300 also includes ball cages 308 with captured ball bearings 310. The ball bearings 310, which mechanically contact the linear-motor rail 312, are lubricated with a lubricant 110 (FIG. 1) that includes an ionic liquid (e.g., is a neat ionic liquid). The linear-motor rail 312 may also be lubricated with a lubricant 110 (FIG. 1) that includes an ionic liquid (e.g., is a neat ionic liquid). In some embodiments, the ball bearings 310 and linear-motor rail 312 are lubricated with the same lubricant 110.

FIG. 4 is a graph showing results 400 quantifying the outgassing of semi-volatile organic compounds (SVOCs) for seven different ionic liquids, as measured using gas-chromatography mass spectrometry (GC-MS). (The metric “RT>2” for the concentration, as shown for the y-axis, refers to the time for a species to go through the GC-MS system. RT is a relative unit used to describe the size and stickiness of molecules.) The seven ionic liquids are EMITFSI, PYR14TFSI, PI13TFSI, N1113TFSI, N1444TFSI, EMIFSI, and PYR14FSI. To obtain these data, the ionic liquids were poured into clean aluminum dishes. The dishes were then placed in outgassing chambers that were under a purge flow of purified N2 gas. A GC-MS sorbent tube containing activated charcoal was attached to the outlet fitting of each outgassing chamber. The SVOCs outgassing from the ionic liquids were captured by the N2 purge gas and followed the flow through the GC-MS sorbent tubes. After approximately 24 hours of sample collection, the sorbent tubes were desorbed and the SVOC outgassing data were captured using a GC-MS instrument. For each ionic liquid, data were captured for outgassing under each of two conditions: Under a first condition 402, the outgassing occurred at 25° C. using the ionic liquid as received. Under a second condition 404, the outgassing occurred at 80° C. after a four-hour bake at 120° C. After the bake (i.e., under the second condition 404), all of the tested ionic liquids had SVOC outgassing rates that were at least two orders of magnitude lower than the post-bake outgassing rates of commercial low-outgassing hydrocarbon-, fluorocarbon-, and silicone-based lubricants. Even before the bake (i.e., under the first condition 402), all of the tested ionic liquids had SVOC outgassing rates that were over an order of magnitude lower than the lowest post-bake outgassing rates of commercial low-outgassing hydrocarbon-, fluorocarbon-, and silicone-based lubricants. These data illustrate that ionic liquids provide the low outgassing rates desired for lubricants in optical systems using ultraviolet light or electron optics (e.g., in semiconductor-wafer or reticle inspection systems and metrology systems).

In addition to the testing that produced the results 400, ionic liquids were tested for anion and cation outgassing. Two ionic liquids, N1444TFSI and EMIFSI, were contained in respective clean aluminum dishes. Scrubber test kits that operate by pumping a gas flow rate of 1 L/min through vials of deionized water were connected to the outgas test chambers housing the aluminum dishes. A separate anion/cation outgassing test was performed on a clean empty aluminum dish, as a control. Salts outgassing from the samples were trapped in the water. After a 24-hour test at 25° C., the vials were sealed and provided to an analytics laboratory, where the anion and cation concentrations trapped in the water were quantified. The results of this testing are shown in Table I. The results for the control have not been subtracted from the results for the two ionic liquids.

TABLE I

| Ionic Liquid | N1444TFSI | EMIFSI | Control |
|---|---|---|---|
| Total Anion Outgassing | 11.3 | 2.6 | 2.4 |
| [ng/(L · cm²)] | | | |
| Total Cation Outgassing | 11.3 | 3.9 | 8.7 |
| [ng/(L · cm²)] | | | |

The amount of outgassing for the control (i.e., the empty aluminum dish) is thus similar to the amount of outgassing for the two ionic liquids. Even with this contribution from the dishes, the results for the ionic liquids are sufficiently low to make the ionic liquids suitable for use as lubricants in optical systems using ultraviolet light or electron optics (e.g., in semiconductor-wafer or reticle inspection systems and metrology systems).

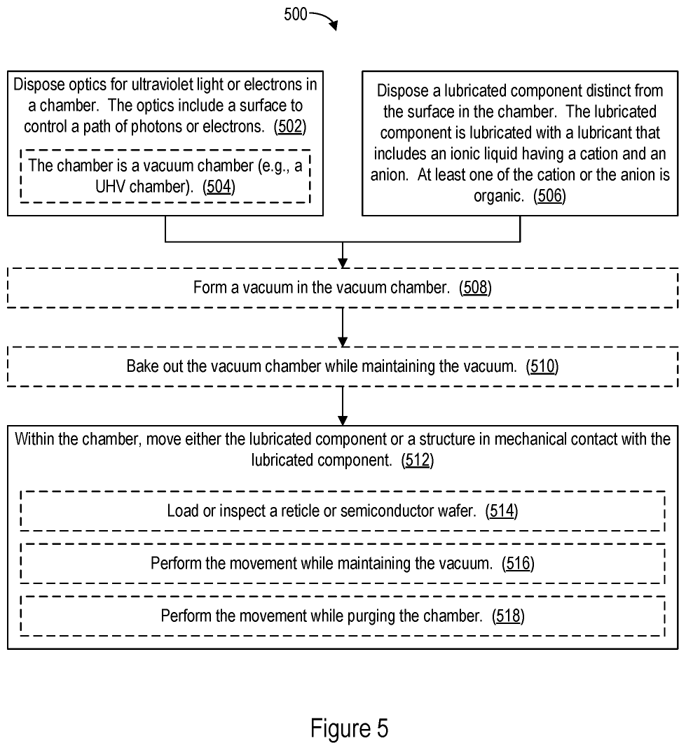

FIG. 5 is a flowchart showing a method 500 of fabricating and operating an optical system in accordance with some embodiments. In the method 500, optics for ultraviolet light or electrons (e.g., for radiation 106, FIG. 1) are disposed (502) in a chamber (e.g., chamber 100, FIG. 1). The optics include a surface (e.g., critical surface 104, FIG. 1) to control a path of photons or electrons. A lubricated component (e.g., lubricated component 108, FIG. 1) distinct from the surface is also disposed (506) in the chamber. The lubricated component is lubricated with a lubricant (e.g., lubricant 110, FIG. 1) that includes an ionic liquid having a cation and an anion. At least one of the cation or the anion is organic. In some embodiments, the chamber is (504) a vacuum chamber (e.g., a UHV chamber).

In some embodiments that include step 504, a vacuum is formed (508) in the vacuum chamber after performing steps 502-506. The vacuum chamber may be baked out (510) while maintaining the vacuum (although the level of the vacuum may vary during bake-out due to outgassing of components in the chamber, including the lubricant). (Alternatively, bake out may be omitted, for example if the vacuum chamber contains temperature-sensitive components.) Bake-out accelerates outgassing and thus results in less outgassing and a corresponding lower level of contamination in the chamber post-bake out.

Within the chamber, either the lubricated component (e.g., a linear motor 206 or 212, FIG. 2) (e.g., a linear motor 300, FIG. 3) or a structure (e.g., a rail 208 or 214, FIG. 2) (e.g., the rail 312, FIG. 3) in mechanical contact with the lubricated component is moved (512). In some embodiments, the structure in mechanical contact with the lubricated component is also lubricated (e.g., with the ionic liquid or with a different ionic liquid). For example, this movement may occur (514) as part of loading or inspecting a reticle or semiconductor wafer. The method 500 thus may include loading a reticle or semiconductor wafer into the chamber and inspecting the reticle or semiconductor wafer in the chamber. In some embodiments, this movement occurs after steps 508 and 510 are performed.

In some embodiments that include step 504 (e.g., that include steps 508 and 510), this movement occurs (516) while maintaining the vacuum. In some other embodiments that do not include step 504, the movement occurs (518) while purging the chamber by flowing purified air through it (e.g., at atmospheric pressure). For example, loading and inspection of a reticle or semiconductor wafer may occur under vacuum or while purging the chamber. The inspection is performed using the ultraviolet light or electrons.

The foregoing description, for purpose of explanation, has been described with reference to specific embodiments. However, the illustrative discussions above are not intended to be exhaustive or to limit the scope of the claims to the precise forms disclosed. Many modifications and variations are possible in view of the above teachings. The embodiments were chosen in order to best explain the principles underlying the claims and their practical applications, to thereby enable others skilled in the art to best use the embodiments with various modifications as are suited to the particular uses contemplated.

What is claimed is:

1. A system, comprising,
optics for ultraviolet light or electrons, the optics being situated in a chamber and comprising a surface to control a path of photons or electrons; and
a lubricated component distinct from the surface and situated in the chamber, the lubricated component being lubricated with a lubricant comprising an ionic liquid having a cation and an anion, wherein at least one of the cation or the anion is organic.

2. The system of claim 1, wherein the cation of the ionic liquid is organic and the anion of the ionic liquid is organic.

3. The system of claim 1, wherein the cation of the ionic liquid is organic and the anion of the ionic liquid is inorganic.

4. The system of claim 1, wherein the anion of the ionic liquid is bis(trifluoromethanesulfonyl)imide (TFSI).

5. The system of claim 1, wherein the anion of the ionic liquid is bis(fluorosulfonyl)imide (FSI).

6. The system of claim 1, wherein the ionic liquid is selected from the group consisting of:
1-ethyl-3-methylimidazolium bis(trifluoromethanesulfonyl)imide (EMITFSI);
1-butyl-1-methylpyrrolidinium bis(trifluoromethanesulfonyl)imide (PYR14TFSI);
1-methyl-1-propylpiperidinium bis(trifluoromethanesulfonyl)imide (PI13TFSI);
N-trimethyl-N-propyl-ammonium bis(trifluoromethanesulfonyl)imide (N1113TFSI);
N-methyl-tri-N-butylammonium bis(trifluoromethanesulfonyl)imide (N1444TFSI);
1-ethyl-3-methylimidazolium bis(fluorosulfonyl)imide (EMIFSI); and
1-butyl-1-methylpyrrolidinium bis(fluorosulfonyl)imide (PYR14FSI).

7. The system of claim 1, wherein the ionic liquid is neat, the lubricant being the neat ionic liquid.

8. The system of claim 1, wherein the chamber is a vacuum chamber.

9. The system of claim 8, wherein the vacuum chamber is an ultra-high vacuum chamber.

10. The system of claim 1, wherein the system is a reticle or semiconductor-wafer inspection system.

11. The system of claim 1, wherein the lubricated component is a rail.

12. The system of claim 11, further comprising a translation stage coupled to the rail, to move along the rail.

13. The system of claim 1, wherein the lubricated component is a motor.

14. The system of claim 13, wherein the motor comprises ball bearings lubricated with the lubricant.

15. The system of claim 1, wherein the optics are for ultraviolet light selected from the group consisting of:
broadband deep ultraviolet light in a wavelength range of 200-400 nm;
vacuum ultraviolet light in a wavelength range of 120-200 nm; and
extreme ultraviolet light at a wavelength of 13.5 nm.

16. The system of claim 1, wherein the optics are electron optics, the system being an electron-beam system.

17. A method, comprising:
disposing optics for ultraviolet light or electrons in a chamber, the optics comprising a surface to control a path of photons or electrons;
disposing a lubricated component distinct from the surface in the chamber, the lubricated component being lubricated with a lubricant comprising an ionic liquid having a cation and an anion, wherein at least one of the cation or the anion is organic; and
within the chamber, moving either the lubricated component or a structure in mechanical contact with the lubricated component.

18. The method of claim 17, wherein the chamber is a vacuum chamber, the method further comprising, after disposing the optics and the lubricated component in the chamber and before performing the moving:
forming a vacuum in the vacuum chamber; and
baking out the vacuum chamber while maintaining the vacuum.

19. The method of claim 18, further comprising, after baking out the vacuum chamber and while maintaining the vacuum:
loading a reticle or semiconductor wafer into the vacuum chamber; and
inspecting the reticle or semiconductor wafer in the vacuum chamber, wherein the moving is performed as part of the inspecting.

20. The method of claim 17, further comprising:
loading a reticle or semiconductor wafer into the chamber;
purging the chamber, comprising flowing air into the chamber; and
while purging the chamber, inspecting the reticle or semiconductor wafer in the chamber, wherein the moving is performed as part of the inspecting.
